(19) United States
(12) Patent Application Publication
(10) Pub. No.: US 2026/0353970 A1
(43) Pub. Date: Nov. 5, 2026

(54) DISPLAY PANEL AND DISPLAY DEVICE

(71) Applicant: Hubei Yangtze Industrial Innovation Center Of Advanced Display Co., Ltd., Wuhan (CN)

(72) Inventors: Shucheng GE, Wuhan (CN); Yu CAI, Wuhan (CN)

(73) Assignee: Hubei Yangtze Industrial Innovation Center Of Advanced Display Co., Ltd., Wuhan (CN)

(21) Appl. No.: 19/725,426

(22) Filed: Jun. 30, 2026

(30) Foreign Application Priority Data
Dec. 31, 2025 (CN) 202512058984.X

(51) Int. Cl. H10K 59/38; H10K 59/35; H10K 59/80

(52) U.S. Cl. CPC H10K 59/38; H10K 59/35; H10K 59/8792

(57) ABSTRACT

A display panel includes display panel includes: a substrate, a light-emitting device layer, and a light-filtering layer. The light-emitting device layer includes a first sub-pixel and a second sub-pixel. The light-filtering layer includes a first shielding layer and a color filter. The first shielding layer includes first shielding portions, a first opening and a second opening. Along a direction perpendicular to a plane of the substrate, the first opening overlaps with the first sub-pixel, the second opening overlaps with the second sub-pixel. The first opening includes the color filter. A thickness of the color filter in the second opening is smaller than a thickness of the color filter in the first opening, and/or along at least one same direction parallel to the plane of the substrate, a width of the color filter in the second opening is smaller than a width of the color filter in the first opening.

### CROSS-REFERENCE TO RELATED APPLICATIONS

The present application claims priority to Chinese Patent Application No. 202512058984.X, entitled “DISPLAY PANEL, AND DISPLAY DEVICE”, filed on Dec. 31, 2025, the content of which is incorporated herein by reference in its entirety.

### TECHNICAL FIELD

The present disclosure relates to the field of display technologies, and, in particular, to a display panel and a display device.

### BACKGROUND

During an operating process of a display panel, different sub-pixels may have different light-emitting durations due to different operation modes. However, a lifetime decay of a sub-pixel is closely related to its light-emitting duration. The longer the light-emitting duration, the faster an aging speed of a light-emitting material, and correspondingly a faster lifetime decay. This non-uniform lifetime decay among different sub-pixels will gradually appear as a usage time of the panel accumulates, thereby easily causing the color cast problem, and thus seriously affecting the display quality.

### SUMMARY

An aspect of the present disclosure provides a display panel. The display panel includes: a substrate, a light-emitting device layer, and a light-filtering layer. The light-emitting device layer is located on a side of the substrate and includes a first sub-pixel and a second sub-pixel. In an embodiment, the light-filtering layer is located on a side of the light-emitting device layer away from the substrate and includes a first shielding layer and a color filter. In an embodiment, the first shielding layer includes first shielding portions, a first opening and a second opening. In an embodiment, the first shielding portions are enclosed to form the first opening and the second opening. In an embodiment, along a direction perpendicular to a plane of the substrate, the first opening overlaps with the first sub-pixel, the second opening overlaps with the second sub-pixel. In an embodiment, the first opening includes the color filter. In an embodiment, in the first opening and the second opening overlapping with the first sub-pixel and the second sub-pixel of at least one same color, along the direction perpendicular to the plane of the substrate, a thickness of the color filter in the second opening is smaller than a thickness of the color filter in the first opening, and/or along at least one same direction parallel to the plane of the substrate, a width of the color filter in the second opening is smaller than a width of the color filter in the first opening.

Another aspect of the present disclosure provides a display device. In an embodiment, the display panel includes: a substrate, a light-emitting device layer, and a light-filtering layer. In an embodiment, the light-emitting device layer is located on a side of the substrate and includes a first sub-pixel and a second sub-pixel. In an embodiment, the light-filtering layer is located on a side of the light-emitting device layer away from the substrate and includes a first shielding layer and a color filter. In an embodiment, the first shielding layer includes first shielding portions, a first opening and a second opening. In an embodiment, the first shielding portions are enclosed to form the first opening and the second opening. In an embodiment, along a direction perpendicular to a plane of the substrate, the first opening overlaps with the first sub-pixel, the second opening overlaps with the second sub-pixel. In an embodiment, the first opening includes the color filter. In an embodiment, in the first opening and the second opening overlapping with the first sub-pixel and the second sub-pixel of at least one same color, along the direction perpendicular to the plane of the substrate, a thickness of the color filter in the second opening is smaller than a thickness of the color filter in the first opening, and/or along at least one same direction parallel to the plane of the substrate, a width of the color filter in the second opening is smaller than a width of the color filter in the first opening.

### BRIEF DESCRIPTION OF DRAWINGS

In order to more clearly illustrate the embodiments of the present disclosure or the technical solutions in the prior art, the accompanying drawings used in the description of the embodiments or the prior art are briefly introduced below. The accompanying drawings in the following description are some embodiments of the present disclosure, and for those skilled in the art, other accompanying drawings may be obtained according to these accompanying drawings.

FIG. 1 is a schematic diagram of a display panel according to some embodiments of the present disclosure;

FIG. 2 is a schematic diagram of a display panel according to some embodiments of the present disclosure;

FIG. 3 is a light-emitting schematic diagram of a sub-pixel in a sharing mode according to some embodiments of the present disclosure;

FIG. 4 is a light-emitting schematic diagram of a sub-pixel in a privacy mode according to some embodiments of the present disclosure;

FIG. 5 is an arrangement schematic diagram of sub-pixels according to some embodiments of the present disclosure;

FIG. 6 is an arrangement schematic diagram of sub-pixels according to some embodiments of the present disclosure;

FIG. 7 is a schematic diagram of a display panel according to some embodiments of the present disclosure;

FIG. 8 is a top view of a second shielding layer and sub-pixels according to some embodiments of the present disclosure;

FIG. 9 is a schematic diagram of a display panel according to some embodiments of the present disclosure;

FIG. 10 is a top view of a second shielding layer and sub-pixels according to some embodiments of the present disclosure;

FIG. 11 is a schematic diagram of a display panel according to some embodiments of the present disclosure;

FIG. 12 is a schematic diagram of a first groove according to some embodiments of the present disclosure;

FIG. 13 is a schematic diagram of a display panel according to some embodiments of the present disclosure;

FIG. 14 is a schematic diagram of a display panel according to some embodiments of the present disclosure;

FIG. 15 is a schematic diagram of a display panel according to some embodiments of the present disclosure;

FIG. 16 is a schematic diagram of a display panel according to some embodiments of the present disclosure;

FIG. 17 is a schematic diagram of a display panel according to some embodiments of the present disclosure;

FIG. 18 is a schematic diagram of a display panel according to some embodiments of the present disclosure;

FIG. 19 is a schematic diagram of a display panel according to some embodiments of the present disclosure;

FIG. 20 is a schematic diagram of a display panel according to some embodiments of the present disclosure; and

FIG. 21 is a schematic diagram of a display device according to some embodiments of the present disclosure.

### DESCRIPTION OF EMBODIMENTS

In order to better understand the technical solutions of the present disclosure, embodiments of the present disclosure will be described in detail below with reference to the drawings.

The described embodiments are merely some of the embodiments of the present disclosure rather than all of the embodiments. Based on the embodiments of the present disclosure, all other embodiments obtained by those of ordinary skill in the art shall fall within the protection scope of the present disclosure.

The terms used in the embodiments of the present disclosure are merely for the purpose of describing specific embodiments, rather than limiting the present disclosure. Singular forms of “a/an”, “said” and “the” used in the embodiments of the present disclosure and the appended claims are also intended to include plural forms, unless the context clearly indicates otherwise.

The term “and/or” used in the context of the present disclosure is to describe a correlation relation of related objects, indicating that there can be three relations, e.g., A and/or B can indicate only A, both A and B, and only B. In addition, the symbol “/” in the context generally indicates that the relation between the objects in front and at the back of “/” is an “or” relationship.

An embodiment of the present disclosure provides a display panel, which may be an organic light-emitting diode (OLED) display panel.

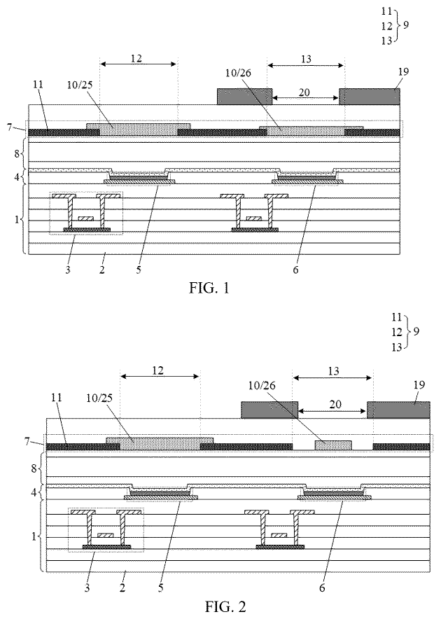

FIG. 1 is a schematic diagram of a display panel according to some embodiments of the present disclosure. FIG. 2 is a schematic diagram of a display panel according to some embodiments of the present disclosure. As shown in FIG. 1 and FIG. 2, the display panel includes a substrate 1, and the substrate 1 includes a base substrate 2 and a pixel circuit 3 located on one side of the base substrate 2.

The display panel further includes a light-emitting device layer 4 located on a side of the substrate 1. The light-emitting device layer 4 includes a first sub-pixel 5 and a second sub-pixel 6. The first sub-pixel 5 and the second sub-pixel 6 may be understood as OLED devices, and emit light under the action of a driving current provided by the pixel circuit 3.

The display panel further includes a light-filtering layer 7, and the light-filtering layer 7 is located on a side of the light-emitting device layer 4 away from the substrate 1. In some embodiments of the present disclosure, an encapsulation layer 8 may be spaced between the light-filtering layer 7 and the light-emitting device layer 4. The light-filtering layer 7 includes a first shielding layer 9 and a color filter 10. The first shielding layer 9 includes first shielding portions 11, and a first opening 12 and a second opening 13. The first shielding portions 11 are enclosed to form the first opening 12 and the second opening 13. Along a direction perpendicular to a plane of the substrate 1, the first opening 12 overlaps with the first sub-pixel 5, the second opening 13 overlaps with the second sub-pixel 6, and the first opening 12 includes the color filter 10.

In the first opening 12 and the second opening 13 overlapping with the first sub-pixel 5 and the second sub-pixel 6 of at least one same color: referring to FIG. 1, along the direction perpendicular to the plane of the substrate 1, a thickness of the color filter 10 in the second opening 13 is smaller than a thickness of the color filter 10 in the first opening 12, and/or, referring to FIG. 2, along at least one same direction parallel to the plane of the substrate 1, a width of the color filter 10 in the second opening 13 is smaller than the width of the color filter 10 in the first opening 12.

It should be noted that, in an embodiment of the present disclosure, “a thickness of the color filter 10 in the second opening 13 is smaller than a thickness of the color filter 10 in the first opening 12” includes the following cases: first, the color filter 10 is disposed in the second opening 13, and the thickness of the color filter 10 in the second opening 13 is relatively small; second, no color filter 10 is disposed in the second opening 13, and the thickness of the color filter 10 in the second opening 13 is 0. “A width of the color filter 10 in the second opening 13 is smaller than a width of the color filter 10 in the first opening 12” includes the following cases: first, the color filter 10 is disposed in the second opening 13, and the width of the color filter 10 in the second opening 13 is relatively small; second, no color filter 10 is disposed in the second opening 13, and the width of the color filter 10 in the second opening 13 is 0.

Additionally, it should also be noted that, when the color filter 10 is disposed in the opening of the first shielding layer 9, a coverage region of the color filter 10 may expand outside the opening of the color filter 10, and the thickness and width of the color filter 10 in the opening refer to the thickness and width of the part of the color filter 10 in the opening.

In an embodiment of the present disclosure, in the first opening 12 and the second opening 13 overlapping with the first sub-pixel 5 and the second sub-pixel 6 of at least one same color, the thickness and/or width of the color filter 10 in the second opening 13 may be configured to be smaller or equal to 0, a loss of incident light by the color filter can be reduced or eliminated, that is, a transmittance of the light-filtering layer 7 at the second opening 13 for the light emitted by the second sub-pixel 6 is improved. The improved transmittance at this position can improve the light efficiency of the second sub-pixel 6, thereby significantly reducing the driving current density required by the second sub-pixel 6 under the same brightness requirement, and thus effectively improving the lifetime decay of the second sub-pixel 6.

The technical solution according to embodiments of the present disclosure may be applied to a scenario in which the second sub-pixel 6 has a larger light-emitting duration, to compensate for the negative influence of the relatively large light-emitting duration of the second sub-pixel 6 on the lifetime decay of the second sub-pixel 6 by using the positive influence of the relatively high transmittance of the light-filtering layer 7 at the second opening 13 on the lifetime decay of the second sub-pixel 6, thereby enabling the lifetime decay degrees of the second sub-pixel 6 and the first sub-pixel 5 to be consistent, and thus effectively alleviating the color cast problem of the display panel.

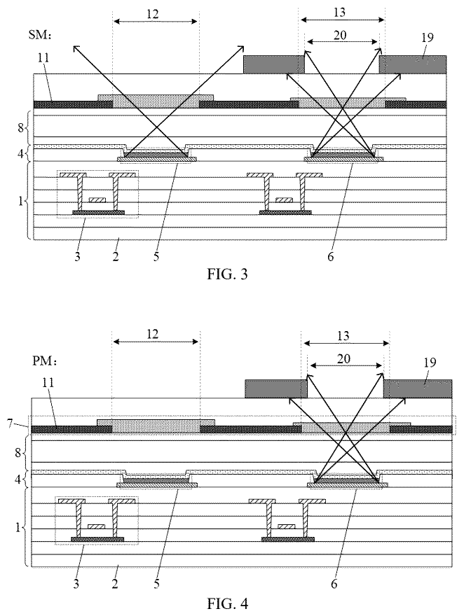

FIG. 3 is a light-emitting schematic diagram of a sub-pixel in a sharing mode according to some embodiments of the present disclosure, and FIG. 4 is a light-emitting schematic diagram of a sub-pixel in a privacy mode according to some embodiments of the present disclosure. Referring to FIG. 1 to FIG. 4, the first sub-pixel 5 is a sharing sub-pixel, and both small-angle light and large-angle light emitted by the first sub-pixel 5 can exit from the panel. The second sub-pixel 6 is a privacy sub-pixel, only small-angle light emitted by the second sub-pixel 6 can exit from the panel, and large-angle light emitted by the second sub-pixel 6 cannot exit from the panel.

The display panel has a sharing mode SM and a privacy mode PM. Referring to FIG. 3, in the sharing mode SM, both the first sub-pixel 5 and the second sub-pixel 6 emit light. Referring to FIG. 4, in the privacy mode PM, only the second sub-pixel 6 emits light, and the first sub-pixel 5 does not emit light.

When the first sub-pixel 5 is a sharing sub-pixel and the second sub-pixel 6 is a privacy sub-pixel: in the sharing mode SM, both the first sub-pixel 5 and the second sub-pixel 6 are controlled to emit light, and then the brightness of the display panel at the large viewing angle is only provided by the first sub-pixel 5, and the brightness of the display panel at the small viewing angle is jointly provided by the first sub-pixel 5 and the second sub-pixel 6, and in this mode, a user can normally view images at both a large viewing angle and a small viewing angle, the brightness of the display panel at the small viewing angle can reach a larger value, thereby further optimizing an image viewing experience at the small viewing angle. In the privacy mode PM, only the second sub-pixel 6 is controlled to emit light, and the first sub-pixel 5 is controlled not to emit light. Then, the brightness of the display panel at a large viewing angle is very low, the user can only normally view the image at a small viewing angle, and cannot view images at a large viewing angle, thereby enabling the display panel to realize a privacy function.

In summary, the first sub-pixel 5 emits light only in the sharing mode SM and does not emit light in the privacy mode PM, while the second sub-pixel 6 emits light in both the sharing mode SM and the privacy mode PM, and the second sub-pixel 6 is in a normally-on state. Therefore, the second sub-pixel 6 has a larger light-emitting duration than the first sub-pixel 5. Based on the design of the color filter in the second opening 13 in this embodiment of the present disclosure, the light efficiency of the second sub-pixel 6 can be improved, and the lifetime decay of the second sub-pixel 6 can be effectively slowed down, thereby enabling the lifetime decay degrees of the two sub-pixels to be consistent, and thus alleviating the color cast problem.

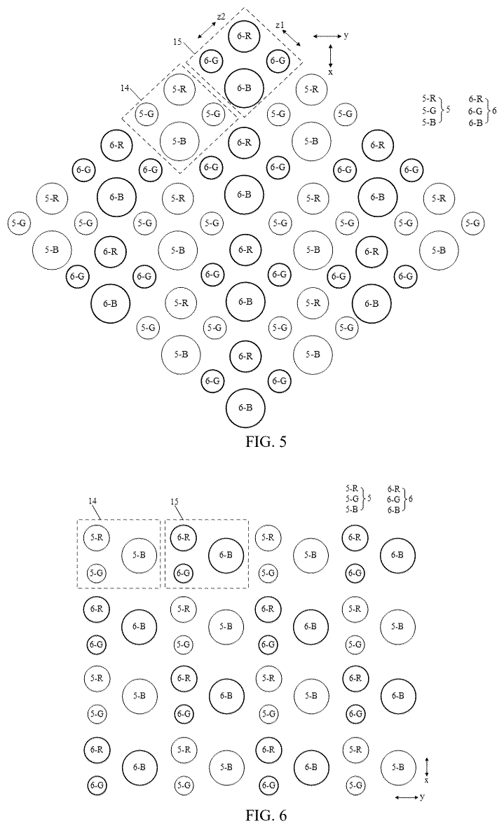

FIG. 5 is an arrangement schematic diagram of sub-pixels according to some embodiments of the present disclosure, and FIG. 6 is an arrangement schematic diagram of sub-pixels according to some embodiments of the present disclosure. As shown in FIG. 5 and FIG. 6, the display panel includes a sharing pixel region 14 and a privacy pixel region 15. The sharing pixel region 14 includes a plurality of first sub-pixels 5, and at least some of the first sub-pixels 5 have different colors. The privacy pixel region 15 includes a plurality of second sub-pixels 6, and at least some of the second sub-pixels 6 have different colors.

In some embodiments of the present disclosure, the first sub-pixel 5 includes a red first sub-pixel 5-R, a green first sub-pixel 5-G, and a blue first sub-pixel 5-B. At least one red first sub-pixel 5-R, at least one green first sub-pixel 5-G, and at least one blue first sub-pixel 5-B are included in the sharing pixel region 14.

The second sub-pixel 6 includes a red second sub-pixel 6-R, a green second sub-pixel 6-G, and a blue second sub-pixel 6-B. The privacy pixel region 15 includes at least one red second sub-pixel 6-R, at least one green second sub-pixel 6-G, and at least one blue second sub-pixel 6-B.

In an embodiment of the present disclosure, a quantity of the first sub-pixels 5 included in the sharing pixel region 14 and a quantity of the second sub-pixels 6 included in the privacy pixel region 15, as well as an arrangement manner of the first sub-pixels 5 in the sharing pixel region 14 and an arrangement manner of the second sub-pixels 6 in the privacy pixel region 15, may be various. Arrangement manners of the sharing pixel region 14 and the privacy pixel region 15 may also be various.

In some embodiments of the present disclosure, referring to FIG. 5, the sharing pixel region 14 includes one red first sub-pixel 5-R, one blue first sub-pixel 5-B, and two green first sub-pixels 5-G. In the sharing pixel region 14, the red first sub-pixels 5-R and the blue first sub-pixels 5-B are arranged along a first direction x, the two green first sub-pixels 5-G are arranged along a second direction y, the first direction x intersects with the second direction y. A line connecting centers of the red first sub-pixels 5-R and the blue first sub-pixels 5-B intersects with a line connecting centers of the two green first sub-pixels 5-G.

The privacy pixel region 15 includes one red second sub-pixel 6-R, one blue second sub-pixel 6-B, and two green second sub-pixels 6-G. In the privacy pixel region 15, the red second sub-pixel 6-R and the blue second sub-pixel 6-B are arranged along the first direction x, the two green second sub-pixels 6-G are arranged along the second direction y. A line connecting centers of the red second sub-pixel 6-R and the blue second sub-pixel 6-B intersects with a line connecting centers of the two green second sub-pixels 6-G.

Further, along a third direction z1 and a fourth direction z2, the sharing pixel region 14 and the privacy pixel region 15 are alternately arranged. The third direction z1 intersects with the fourth direction z2. An included angle between the third direction z1 and the first direction x, and an included angle between the third direction z1 and the second direction y are neither equal to 0 nor equal to 90°.

In some embodiments of the present disclosure, referring to FIG. 6, the sharing pixel region 14 includes one red first sub-pixel 5-R, one green first sub-pixel 5-G and one blue first sub-pixel 5-B. In the sharing pixel region 14, the red first sub-pixel 5-R and the blue first sub-pixel 5-B are arranged along the first direction x. Along the second direction y, the green first sub-pixel 5-G overlaps with an interval between the red first sub-pixel 5-R and the blue first sub-pixel 5-B.

The privacy pixel region 15 includes a red second sub-pixel 6-R, a green second sub-pixel 6-G, and a blue second sub-pixel 6-B. In the privacy pixel region 15, the red second sub-pixel 6-R and the blue second sub-pixel 6-B are arranged along the first direction x. Along the second direction y, the green second sub-pixel 6-G overlaps with an interval between the red second sub-pixel 6-R and the blue second sub-pixel 6-B.

Further, along the first direction x and the second direction y, the sharing pixel region 14 and the privacy pixel region 15 are alternately arranged.

Each of the above designs can realize that the privacy pixel regions 15 and the sharing pixel regions 14 are distributed in an alternating manner by being interspersed along two directions within an entire display region, which improves display effects of the display panel in the two modes.

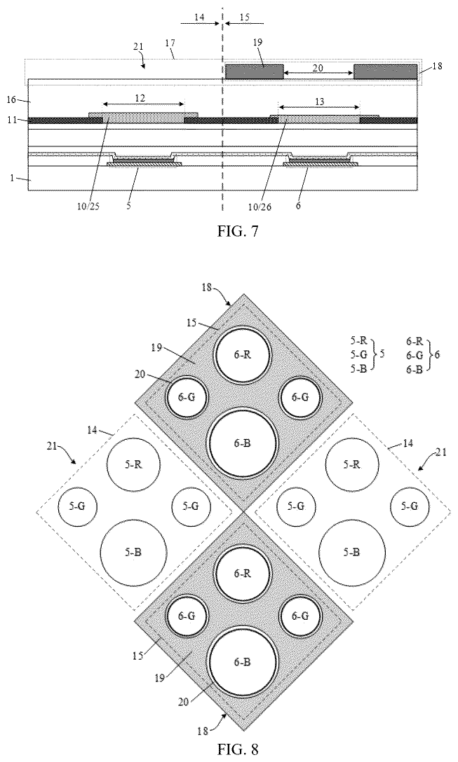

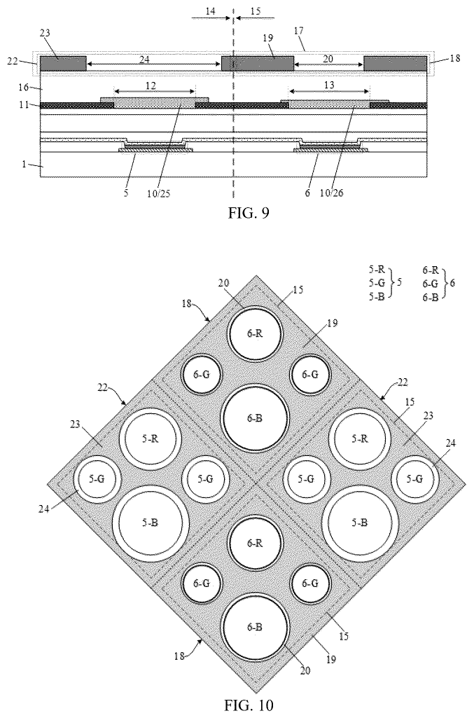

FIG. 7 is a schematic diagram of a display panel according to some embodiments of the present disclosure. FIG. 8 is a top view of a second shielding layer and sub-pixels according to some embodiments of the present disclosure. FIG. 9 is a schematic diagram of a display panel according to some embodiments of the present disclosure. FIG. 10 is a top view of a second shielding layer and sub-pixels according to some embodiments of the present disclosure. As shown in FIG. 7 to FIG. 10, the display panel further includes a spacer layer 16 and a second shielding layer 17, the spacer layer 16 is located on a side of the light-filtering layer 7 away from the substrate 1, and the second shielding layer 17 is located on a side of the spacer layer 16 away from the substrate 1.

The second shielding layer 17 includes a first sub-portion 18 located in the privacy pixel region 15. The first sub-portion 18 includes a second shielding portion 19 and a third opening 20 enclosed by the second shielding portion 19. The third opening 20 overlaps with the second sub-pixel 6 along the direction perpendicular to the plane of the substrate 1.

Compared with the first shielding layer 9, the second shielding layer 17 is spaced further from the light-emitting device layer 4. Referring to FIG. 2 and FIG. 3, when the large-angle light emitted through the second opening 13 is shielded by the second shielding portion 19 when continuing to transmit upward and cannot exit from the panel, thereby realizing narrowing the light-emitting angle range of the second sub-pixel 6.

Further, along at least one same direction, a width of the third opening 20 is smaller than a width of the second opening 13, and/or along the direction perpendicular to the plane of the substrate 1, a thickness of the second shielding portion 19 is greater than a thickness of the first shielding portion 11, thereby enabling the second shielding portion 19 to shield light within a larger angle range, and thus further narrowing the viewing angle in the privacy mode.

In some embodiments of the present disclosure, referring again to FIG. 7 and FIG. 8, the second shielding layer 17 includes a hollow 21. Along the direction perpendicular to the plane of the substrate 1, the hollow 21 overlaps with the sharing pixel region 14, for example, the sharing pixel region 14 may be entirely exposed in the hollow 21.

In this structure, the light emitted through the first opening 12 directly passes through the hollow 21 when being transmitted to the second shielding layer 17, the second shielding layer 17 does not affect the transmission of the light, more large-angle light emitted by the first sub-pixel 5 can exit, making an image quality at a large viewing angle in the sharing mode SM superior.

In some embodiments of the present disclosure, referring again to FIG. 9 and FIG. 10, the second shielding layer 17 includes a second sub-portion 22 located in the sharing pixel region 14. The second sub-portion 22 includes a third shielding portion 23 and a fourth opening 24 enclosed by the third shielding portion 23. Along the direction perpendicular to the plane of the substrate 1, the fourth opening 24 overlaps with the first sub-pixel 5. In the first opening 12 and the fourth opening 24 that overlap a same first sub-pixel 5, an orthographic projection of the first opening 12 on the substrate 1 is located within an orthographic projection of the fourth opening 24 on the substrate 1, and an interval exists between an orthographic projection of an edge of the first opening 12 on the substrate 1 and an orthographic projection of an edge of the fourth opening 24 on the substrate 1.

In this structure, the second shielding layer 17 may also be located in the sharing pixel region 14, but the size of the fourth opening 24 of the second shielding layer 17 in the sharing pixel region 14 is greater than the size of the corresponding first opening 12, thereby preventing the third shielding portion 23 from shielding the large-angle light transmitted through the first opening 12, and thus ensuring that the large-angle light can exit normally. In this structure, in the non-opening regions of the sharing pixel region 14 and the privacy pixel region 15, the first shielding portion 11 and the second shielding portion 19 are both provided for double-layer shielding, the shielding degrees of the two pixel regions tend to be consistent, and the reflection uniformity of the display panel is superior.

In some embodiments of the present disclosure, referring again to FIG. 1, at least part of the second openings 13 includes the color filter 10.

The color filter 10 includes a first color filter 25 and a second color filter 26, at least part of the first color filter 25 is located in the first opening 12, and at least part of the second color filter 26 is located in the second opening 13.

In at least part of the second color filter 26 and the first color filter 25 of a same color, a thickness of the second color filter 26 in the second opening 13 is smaller than a thickness of the first color filter 25 in the first opening 12 along the direction perpendicular to the plane of the substrate 1.

In this configuration, the second color filter 26 is correspondingly disposed at at least part of the second sub-pixel 6. Compared with the first color filter 25 of a same color, the part of the second color filter 26 is thinner. Therefore, light emitted by the second sub-pixel 6 generates smaller light loss when passing through the second color filter 26, thereby improving the light efficiency of the second sub-pixel 6, and thus slowing down the lifetime decay thereof.

Additionally, after the second color filter 26 is disposed, the second color filter 26 may be used to filter out stray wavelengths in a light-emitting spectrum of the second sub-pixel 6, purifying a spectrum of light of a corresponding color, thereby improving color gamut purity and achieving a superior display effect. Additionally, after the second color filter 26 is disposed, the second color filter 26 may be used to absorb ambient light, reducing reflection of ambient light.

FIG. 11 is a schematic diagram of a display panel according to some embodiments of the present disclosure. As shown in FIG. 11, the second opening 13 includes a type-A opening 27, the second color filter 26 includes a type-A color filter 28, and at least part of the type-A color filter 28 is located in the type-A opening 27.

The first shielding portion 11 includes a first groove 29. A distance between the first groove 29 and the type-A opening 27 closest thereto is smaller than a distance between the first groove 29 and the first opening 12 closest thereto. For example, the first groove 29 is located in the privacy pixel region 15 and is adjacent to the second sub-pixel 6.

In the type-A color filter 28 and the first color filter 25 of a same color, along the direction perpendicular to the plane of the substrate 1, a thickness of the type-A color filter 28 in the type-A opening 27 is smaller than a thickness of the first color filter 25 in the first opening 12.

The first shielding portion 11 is provided with a first groove 29 at a position adjacent to the type-A opening 27. When the color filter material is coated, the color filter material is filled in the first groove 29 when flowing near the type-A opening 27, thereby naturally reducing the thickness of the color filter material in the nearby region, and further thinning the type-A color filter 28 in the type-A opening 27, and thus resulting in the thickness difference between the type-A color filter 28 and the first color filter 25 of a same color.

In the embodiments of the present disclosure, with reference to FIG. 1, the thickness difference between the second color filter 26 and the first color filter 25 may also be realized via a halftone mask process.

However, compared to adopting the halftone mask process, the above manner of thinning the second color filter 26 by using the first groove 29 does not need to use an expensive semi-transparent mask plate in the process, which can reduce the processing cost to a great extent and has higher film formation stability.

Further, referring again to FIG. 11, along the direction perpendicular to the plane of the substrate 1, the type-A color filter 28 overlaps with the first groove 29, and at least part of the type-A color filter 28 is located in the first groove 29.

The type-A color filter 28 overlaps with the first groove 29, which means that the coverage region of the type-A color filter 28 is expanded outside the type-A opening 27, thereby providing a certain margin for the position shift of the type-A opening 27, the type-A color filter 28 caused by process precision and other reasons. Even if some deviation exists in the actual position of the type-A opening 27 or the type-A color filter 28, it can still be ensured that the type-A color filter 28 completely covers the type-A opening 27.

In other words, on the premise of a certain margin, the type-A color filter 28 overlaps with the first groove 29, which means that the first groove 29 is not too far away from the type-A opening 27, and the first groove 29 may have a more obvious influence on the flow of the color filter material at the type-A opening 27, thereby resulting in a thinner design of the type-A color filter 28, and thus reducing the light loss of the second sub-pixel 6.

In some embodiments of the present disclosure, referring again to FIG. 11, a depth of the first groove 29 is d1, and a thickness of the first shielding portion 11 at a non-groove position is d2, where d1≤1/3×d2.

When the first groove 29 is provided, the depth of the first groove 29 is designed to be smaller than or equal to one third of the thickness of the first shielding portion 11 at the non-groove position, which can prevent the first groove 29 from being too deep, thereby preventing the light shielding capability of the first shielding portion 11 at the position from being significantly deteriorated, and thus ensuring the stability of the shielding performance of the first shielding portion 11.

In some embodiments of the present disclosure, referring again to FIG. 11, along the arrangement direction of the first groove 29 and the adjacent opening 27, the width w of the first groove 29 is smaller than or equal to 4 μm.

As described above, the privacy pixel region 15 includes a plurality of second sub-pixels 6, and the first grooves 29 are spaced between adjacent second sub-pixels 6. By configuring the width of the first groove 29 to be smaller than or equal to 4 μm, the influence on a spacing between adjacent second sub-pixels 6 due to the arrangement of the first groove 29 can be avoided, thereby ensuring a high resolution and improving a display effect in the privacy mode. In other words, under a scenario where the spacing is fixed, the first grooves 29 may be correspondingly provided at the peripheries of two adjacent second sub-pixels 6 respectively, thereby thinning the type-A color filters 28 corresponding to more second sub-pixels 6 by using the first grooves 29.

In some embodiments of the present disclosure, referring again to FIG. 11, a distance d3 between the type-A opening 27 and the first groove 29 closest thereto is greater than or equal to 3 μm, and/or the distance d3 between the type-A opening 27 and the first groove 29 closest thereto is smaller than or equal to 9 μm.

The design of 3 μm can cover the position offset of the type-A opening 27 and the first groove 29, and even if the position deviation exists between the type-A opening 27 and the first groove 29, it can still be ensured that a certain interval exists between the first groove 29 and the type-A opening 27. The design of 9 μm can prevent the first groove 29 from being too far away from the type-A opening 27, and ensure that the design of the first groove 29 can significantly thin the second color filter 26 in the type-A opening 27.

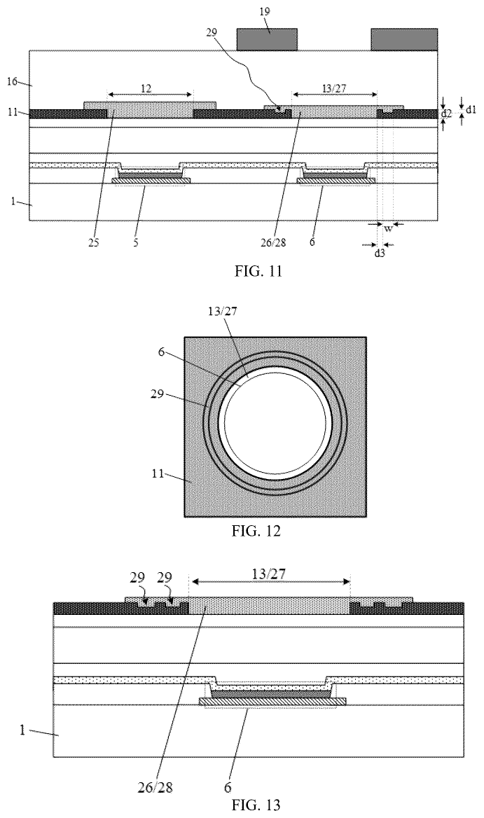

FIG. 12 is a schematic diagram of a first groove according to some embodiments of the present disclosure. As shown in FIG. 12, the first groove 29 at least partially surrounds the type-A opening 27, for example, the first groove 29 may be an annular structure surrounding the type-A opening 27.

The first groove 29 at least partially surrounds the type-A opening 27, which can affect the flow of the color filter material at different orientations surrounding the periphery of the type-A opening 27, thereby improving the thickness uniformity of the color filter material in the type-A opening 27 and improving the film-forming quality of the type-A color filter 28.

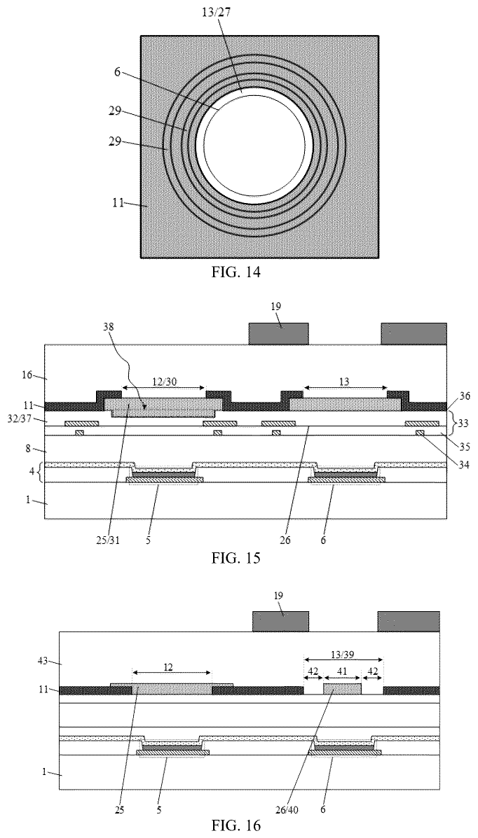

FIG. 13 is a schematic diagram of a display panel according to some embodiments of the present disclosure, and FIG. 14 is a schematic diagram of a display panel according to some embodiments of the present disclosure. As shown in FIG. 13 and FIG. 14, at least two first grooves 29 are formed around the type-A opening 27, and widths of the at least two first grooves 29 can be same or different.

In this design, a larger quantity of first grooves 29 may be used to satisfy the filling requirement of the color filter material, and the color filter material in the type-A opening 27 may be thinner, thereby achieving a superior design for the thickness of the second color filter 26.

FIG. 15 is a schematic diagram of a display panel according to some embodiments of the present disclosure. As shown in FIG. 15, the first opening 12 includes a first sub-opening 30, the first color filter 25 includes a first color sub-filter 31, and at least part of the first color sub-filter 31 is located in the first sub-opening 30.

The display panel further includes a first film layer 32 adjacent to the light-filtering layer 7 and located between the light-filtering layer 7 and the light-emitting device layer 4.

In some embodiments of the present disclosure, a touch layer 33 is further included between the light-filtering layer 7 and the light-emitting device layer 4. The touch layer 33 includes a first electrode layer 34, a first insulating layer 35 located on a side of the first electrode layer 34 away from the substrate 1, a second electrode layer 36 located on a side of the first insulating layer 35 away from the substrate 1, and a second insulating layer 37 located on a side of the second electrode layer 36 away from the substrate 1. At least one of the first electrode layer 34 and the second electrode layer 36 includes a touch electrode, and at least one of the first electrode layer 34 and the second electrode layer 36 includes a touch line. The first film layer 32 may be a second insulating layer 37.

The first film layer 32 includes a second groove 38. Along the direction perpendicular to the plane of the substrate 1, the second groove 38 overlaps with the first sub-opening 30, and at least part of the first color filter 31 is located in the second groove 38.

In the first color sub-filter 31 and the second color filter 26 of a same color, along the direction perpendicular to the plane of the substrate 1, a thickness of the first color sub-filter 31 in the first sub-opening 30 is greater than a thickness of the second color filter 26 in the second opening 13.

In this structure, the first film layer 32 is provided with a second groove 38 at the position of the first sub-opening 30. When the color filter material is coated, the color filter material is deposited in the second groove 38, thereby resulting in a larger thickness of the formed first color sub-filter 31 in the first sub-opening 30, and thus forming a thickness difference between the first color sub-filter 31 and the second color filter 26 of a same color.

Additionally, compared to adopting the halftone mask process, the above manner of thickening the first color filter 25 by using the second groove 38 does not need to use an expensive semi-transparent mask plate in the process, which can reduce the processing costs to a great extent and has higher film formation stability.

In some embodiments of the present disclosure, referring again to FIG. 2, at least part of the second openings 13 includes the color filter 10.

The color filter 10 includes a first color filter 25 and a second color filter 26, at least part of the first color filter 25 is located in the first opening 12, and at least part of the second color filter 26 is located in the second opening 13.

In at least part of the second color filter 26 and the first color filter 25 of a same color, along at least one same direction parallel to the plane of the substrate 1, a width of the second color filter 26 in the second opening 13 is smaller than a width of the first color filter 25 in the first opening 12.

In this configuration, the second color filter 26 is correspondingly disposed at at least part of the second sub-pixels 6, but compared to the first color filter 25 of a same color, this part of the second color filter 26 is narrower, that is, only the second opening 13 is partially covered. Therefore, the light emitted by the second sub-pixel 6 generates smaller light loss when passing through the second opening 13, thereby improving the light efficiency of the second sub-pixel 6, and thus slowing down the lifetime decay thereof.

Additionally, after the second color filter 26 is disposed, the second color filter 26 may be used to filter out stray wavelengths in a light-emitting spectrum of the second sub-pixel 6, purifying a spectrum of light of a corresponding color, thereby improving color gamut purity and achieving a superior display effect. Additionally, after the second color filter 26 is disposed, the second color filter 26 may be used to absorb ambient light, reducing reflection of ambient light.

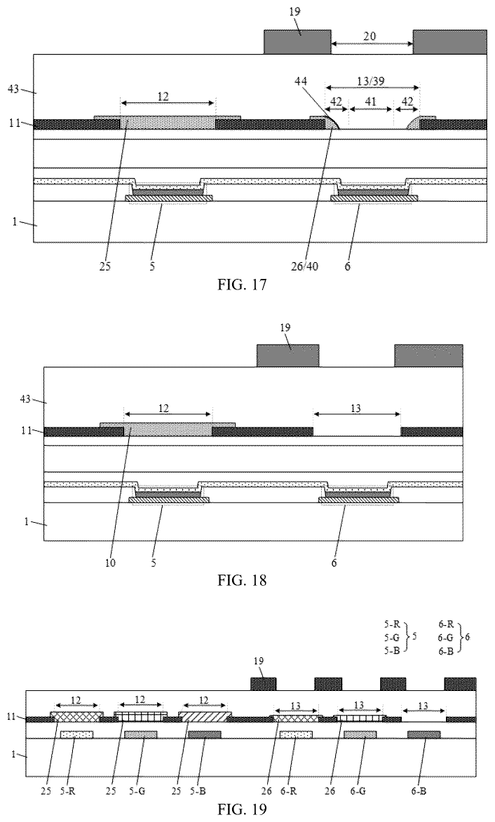

FIG. 16 is a schematic diagram of a display panel according to some embodiments of the present disclosure, and FIG. 17 is a schematic diagram of a display panel according to some embodiments of the present disclosure. As shown in FIG. 16 and FIG. 17, the second opening 13 includes a type-B opening 39, the second color filter includes a type-B color filter 40, and the type-B color filter 40 is located in the type-B opening 39.

Along the direction perpendicular to the plane of the substrate 1, the type-B color filter 40 overlaps with a partial region of the type-B opening 39 and does not overlap another partial region of the type-B opening 39.

In this structure, the type-B color filter 40 is only located in the partial region of the type-B opening 39, and the partial region of the type-B opening 39 is not covered by the color filter. Therefore, a part of light emitted by the second sub-pixel 6 does not need to pass through the color filter when being emitted by the type-B opening 39, thereby reducing the light loss and further improving the light efficiency.

In some embodiments of the present disclosure, referring again to FIG. 16, the type-B opening 39 includes a middle opening region 41 and an edge opening region 42 surrounding the middle opening region 41.

Along the direction perpendicular to the plane of the substrate 1, at least part of the type-B color filter 40 overlaps with the middle opening region 41 and does not overlap with the edge opening region 42.

Since the user may view the screen at a small viewing angle more, and the type-B color filter 40 is disposed at the middle position of the type-B opening 39, the type-B color filter 40 may better filter out stray light at the small viewing angle, thereby improving the color purity at the small viewing angle, and thus optimizing the display effect at the small viewing angle.

In some embodiments of the present disclosure, referring again to FIG. 17, the type-B opening 39 includes a middle opening region 41 and an edge opening region 42 surrounding the middle opening region 41.

Along the direction perpendicular to the plane of the substrate 1, at least part of the type-B color filter 40 overlaps with the edge opening region 42 and does not overlap with the middle opening region 41.

The display panel further includes a second film layer 43 adjacent to the light-filtering layer 7 and located on a side of the light-filtering layer 7 away from the substrate 1. A refractive index of the second film layer 43 is greater than a refractive index of the type-B color filter 40. For example, the refractive index of the color filter material may range from 1.55 to 1.65, and the refractive index of the second film layer 43 may range from 1.7 to 1.75.

In this structure, the type-B color filter 40 is disposed at an edge position of the type-B opening 39, and the second film layer 43 above the light-filtering layer 7 is designed in a matching manner. By making the refractive index of the second film layer 43 greater than the refractive index of the type-B color filter 40, the large-angle light emitted by the second sub-pixel 6 will be refracted or totally reflected when transmitted to the sidewall of the type-B color filter 40, that is, transmitted to the interface between the type-B color filter 40 and the second film layer 43, and then converted into small-angle light to exit. In this way, the large-angle light that cannot exit originally can be converted into small-angle light to exit through the third opening 20, thereby further improving the light-emitting brightness of the second sub-pixel 6 at a small viewing angle, and thus optimizing the display effect in the privacy mode.

Further, referring again to FIG. 17, the type-B color filter 40 includes a sidewall 44. A distance between the sidewall 44 and the substrate 1 increases along a direction from the middle opening region 41 toward the edge opening region 42.

In some embodiments of the present disclosure, the type-B color filter 40 includes a bottom surface adjacent to one side of the substrate 1 and a sidewall 44 intersecting with the bottom surface. Along a direction away from the substrate 1, the sidewall inclines toward a direction adjacent to the bottom surface.

In the above structure, the sidewall of the type-B color filter 40 is an inclined sidewall, thereby increasing the contact area between the type-B color filter 40 and the second film layer 43, enabling more large-angle light to fall on the interface between the type-B color filter 40 and the second film layer 43, and further converting more large-angle light into small-angle light to exit.

FIG. 18 is a schematic diagram of a display panel according to some embodiments of the present disclosure. As shown in FIG. 18, a thickness and a width of a color filter 10 in at least part of the second opening 13 are 0, that is, no color filter 10 is disposed in the part of the second opening 13.

The color filter in at least part of the second opening 13 is directly removed, and the light emitted by the corresponding second sub-pixel 6 can be directly emitted through the second opening 13 without passing through the color filter, thereby eliminating the light loss caused by the color filter, improving the light efficiency of this part of the second sub-pixel 6 to a larger extent, and thus slowing down the lifetime decay of the part of the second sub-pixel 6 to a larger extent.

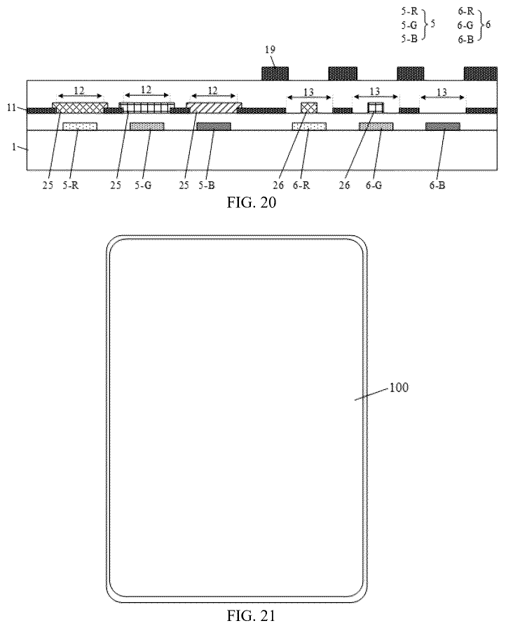

FIG. 19 is a schematic diagram of a display panel according to some embodiments of the present disclosure, and FIG. 20 is a schematic diagram of a display panel according to some embodiments of the present disclosure. As shown in FIG. 19 and FIG. 20, the second sub-pixel 6 includes a red second sub-pixel 6-R. Along the direction perpendicular to the plane of the substrate 1, the red second sub-pixel 6-R overlaps with the second color filter 26. That is, the second color filter 26 is disposed at the second opening 13 corresponding to the red second sub-pixel 6-R, and a thickness and/or a width of the red second color filter is smaller than a thickness and/or a width of the red first color filter 25.

In an alternative embodiment, the second sub-pixel 6 includes a green second sub-pixel 6-G, and the green second sub-pixel 6-G overlaps with the second color filter 26 along the direction perpendicular to the plane of the substrate 1. That is, the second color filter 26 is disposed at the second opening 13 corresponding to the green second sub-pixel 6-G, and a thickness and/or a width of the green second color filter is smaller than a thickness and/or a width of the green first color filter 25.

Compared to the blue sub-pixel, lifetime decay speeds of a red sub-pixel and a green sub-pixel are relatively slow. Therefore, a thinner or narrower second color filter 26 can be provided for the red second sub-pixel 6-R and the green second sub-pixel 6-G. The purity of red light and green light is higher while the lifetime decay of the red second sub-pixel 6-R and the green second sub-pixel 6-G is slowed down by using the second color filter 26 under this design.

In some embodiments of the present disclosure, referring again to FIG. 19 and FIG. 20, the second sub-pixel 6 includes a blue second sub-pixel 6-B, and in the second opening 13 overlapping with the blue second sub-pixel 6-B along the direction perpendicular to the plane of the substrate 1, a thickness and a width of the color filter 10 in the second opening 13 are 0, that is, no color filter is disposed in the second opening 13 corresponding to the blue second sub-pixel 6-B.

Compared with the red sub-pixel and the green sub-pixel, the lifetime decay of the blue sub-pixel is faster. Therefore, when the light-emitting durations of the first sub-pixel 5 and the second sub-pixel 6 are different, the lifetime difference between the blue second sub-pixel 6-B and the blue first sub-pixel 5-B is more obvious. In this regard, no color filter may be provided in the second opening 13 corresponding to the blue second sub-pixel 6-B, eliminating the loss of light emitted by the blue second sub-pixel 6-B by the color filter, increasing the light efficiency of the blue second sub-pixel 6-B to a larger degree, slowing down the lifetime decay thereof to a larger degree, and further better making lifetime decay degrees of the blue second sub-pixel 6-B and the blue first sub-pixel 5-B consistent.

Additionally, it should be noted that the thicknesses of the first color filters 25 corresponding to the first sub-pixels 5 of different colors may be the same or different. When the second sub-pixels 6 are correspondingly provided with the second color filters 26, the thickness design between the second color filters 26 of different colors may follow the thickness design between the first color filters 25 of different colors.

For example, when the thicknesses of the first color filters 25 corresponding to the first sub-pixels 5 of different colors are the same, the thicknesses of the second color filters 26 corresponding to the second sub-pixels 6 of different colors are the same. When the thicknesses of the first color filters 25 corresponding to the first sub-pixels 5 of different colors are different, the thicknesses of the second color filters 26 corresponding to the second sub-pixels 6 of different colors are also different. It only needs to make the thickness of the second color filter 26 smaller than the thickness of the first color filter 25 of a same color.

Similarly, along at least one same direction, the widths of the first openings 12 corresponding to the first sub-pixels 5 of different colors may be the same or different, such that the widths of the first color filters 25 corresponding to the first sub-pixels 5 of different colors may also be the same or different. When the second sub-pixels 6 are correspondingly provided with the second color filters 26, the width design between the second color filters 26 of different colors may follow the width design between the first color filters 25 of different colors.

For example, when the widths of the first color filters 25 corresponding to the first sub-pixels 5 of different colors are the same, the widths of the second color filters 26 corresponding to the second sub-pixels 6 of different colors are the same. When the widths of the first color filters 25 corresponding to the first sub-pixels 5 of different colors are different, the widths of the second color filters 26 corresponding to the second sub-pixels 6 of different colors are different. It only needs to make the width of the second color filter 26 smaller than the width of the first color filter 25 of a same color.

Based on a same inventive concept, the present disclosure further provides a display device. FIG. 21 is a schematic diagram of a display device provided by an embodiment of the present disclosure. As shown in FIG. 21, the display device includes the above display panel 100. The display device shown in FIG. 21 is merely illustrative, and the display device may be any electronic device having a display function such as a mobile phone, a tablet computer, a notebook computer, an e-book, and a television.

The above are merely exemplary embodiments of the present disclosure, which, as mentioned above, are not used to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to be limited thereto. Although the present disclosure has been described in detail with reference to the foregoing embodiments, those skilled in the art can understand that the present disclosure is not limited to the specific embodiments described herein, and can make various modifications, readjustments, and substitutions without departing from the scope of the present disclosure.

What is claimed is:

1. A display panel, comprising:
a substrate;
a light-emitting device layer, located on a side of the substrate and comprising a first sub-pixel and a second sub-pixel; and
a light-filtering layer located on a side of the light-emitting device layer away from the substrate and comprising a first shielding layer and a color filter, wherein the first shielding layer comprises first shielding portions, a first opening, and a second opening,
wherein the first shielding portions are enclosed to form the first opening and the second opening, and, along a direction perpendicular to a plane of the substrate, the first opening overlaps with the first sub-pixel, the second opening overlaps with the second sub-pixel, and the first opening comprises the color filter,
wherein, in the first opening and the second opening overlapping with the first sub-pixel and the second sub-pixel of at least one same color, along the direction perpendicular to the plane of the substrate, a thickness of the color filter in the second opening is smaller than a thickness of the color filter in the first opening, and/or along at least one same direction parallel to the plane of the substrate, a width of the color filter in the second opening is smaller than a width of the color filter in the first opening.

2. The display panel according to claim 1, wherein the first sub-pixel is a sharing sub-pixel, and the second sub-pixel is a privacy sub-pixel;
wherein the display panel has a sharing mode and a privacy mode;
wherein in the sharing mode, the first sub-pixel and the second sub-pixel emit light; and
wherein in the privacy mode, the second sub-pixel emits light, and the first sub-pixel does not emit light.

3. The display panel according to claim 2, wherein the display panel comprises a sharing pixel region and a privacy pixel region, the sharing pixel region comprises a plurality of first sub-pixels, and the privacy pixel region comprises a plurality of second sub-pixels;
wherein the display panel further comprises a spacer layer and a second shielding layer, the spacer layer is located on a side of the light-filtering layer away from the substrate, and the second shielding layer is located on a side of the spacer layer away from the substrate; and
wherein the second shielding layer comprises a first sub-portion located in the privacy pixel region, the first sub-portion comprises a second shielding portion and a third opening enclosed by the second shielding portion, and the third opening overlaps with the second sub-pixel along the direction perpendicular to the plane of the substrate.

4. The display panel according to claim 3, wherein
the second shielding layer comprises a hollow, and the hollow overlaps with the sharing pixel region along the direction perpendicular to the plane of the substrate; or
the second shielding layer comprises a second sub-portion located in the sharing pixel region, the second sub-portion comprises a third shielding portion and a fourth opening enclosed by the third shielding portion, along the direction perpendicular to the plane of the substrate, the fourth opening overlaps with the first sub-pixel, and in the first opening and the fourth opening that overlap a same first sub-pixel, an orthographic projection of the first opening on the substrate is located within an orthographic projection of the fourth opening on the substrate, and an interval exists between an orthographic projection of an edge of the first opening on the substrate and an orthographic projection of an edge of the fourth opening on the substrate.

5. The display panel according to claim 1, wherein at least part of the second opening comprises the color filter;
wherein the color filter comprises a first color filter and a second color filter, at least part of the first color filter is located in the first opening, and at least part of the second color filter is located in the second opening;
wherein, in at least part of the second color filter and the first color filter of a same color, along the direction perpendicular to the plane of the substrate, a thickness of the second color filter in the second opening is smaller than a thickness of the first color filter in the first opening.

6. The display panel according to claim 5, wherein the second opening comprises a type-A opening, the second color filter comprises a type-A color filter, and at least part of the type-A color filter is located in the type-A opening;
wherein the first shielding portion comprises a first groove, and a distance between the first groove and a type-A opening closest to the first groove is smaller than a distance between the first groove and a first opening closest to the first groove; and
wherein, in the type-A color filter and the first color filter that have a same color, along the direction perpendicular to the plane of the substrate, a thickness of the type-A color filter in the type-A opening is smaller than the thickness of the first color filter in the first opening.

7. The display panel according to claim 6, wherein, along the direction perpendicular to the plane of the substrate, the type-A color filter overlaps with the first groove, and at least part of the type-A color filter is located in the first groove.

8. The display panel according to claim 6, wherein a depth of the first groove is d1, and a thickness of the first shielding portion at a non-groove position is d2, wherein d1≤1/3×d2.

9. The display panel according to claim 6, wherein, along an arrangement direction of the first groove and the adjacent type-A opening, a width of the first groove is smaller than or equal to 4 μm.

10. The display panel according to claim 6, wherein the distance between the type-A opening and the first groove closest to the type-A opening is greater than or equal to 3 μm, and/or, the distance between the type-A opening and the first groove closest to the type-A opening is smaller than or equal to 9 μm.

11. The display panel according to claim 6, wherein the first groove at least partially surrounds the type-A opening.

12. The display panel according to claim 6, wherein at least two first grooves are formed around the type-A opening.

13. The display panel according to claim 5, wherein the first opening comprises a first sub-opening, the first color filter comprises a first color sub-filter, and at least part of the first color sub-filter is located in the first sub-opening;
wherein the display panel further comprises a first film layer adjacent to the light-filtering layer and located between the light-filtering layer and the light-emitting device layer, the first film layer comprises a second groove, along the direction perpendicular to the plane of the substrate, the second groove overlaps with the first sub-opening, and at least part of the first color sub-filter is located in the second groove; and
wherein, in the first color sub-filter and the second color filter of a same color, along the direction perpendicular to the plane of the substrate, a thickness of the first color sub-filter in the first sub-opening is greater than the thickness of the second color filter in the second opening.

14. The display panel according to claim 1, wherein at least part of the second opening comprises the color filter; and
wherein the color filter comprises a first color filter and a second color filter, at least part of the first color filter is located in the first opening, and at least part of the second color filter is located in the second opening, and
wherein in some of the second color filter and the first color filter that have a same color, along at least one same direction parallel to the plane of the substrate, a width of the second color filter in the second opening is smaller than a width of the first color filter in the first opening.

15. The display panel according to claim 14, wherein the second opening comprises a type-B opening, the second color filter comprises a type-B color filter, and the type-B color filter is located in the type-B opening; and
wherein, along the direction perpendicular to the plane of the substrate, the type-B color filter overlaps with a partial region of the type-B opening and does not overlap with another partial region of the type-B opening.

16. The display panel according to claim 15, wherein
the type-B opening comprises a middle opening region and an edge opening region surrounding the middle opening region; and
along the direction perpendicular to the plane of the substrate, at least part of the type-B color filter overlaps with the middle opening region and does not overlap with the edge opening region.

17. The display panel according to claim 15, wherein the type-B opening comprises a middle opening region and an edge opening region surrounding the middle opening region;
wherein, along the direction perpendicular to the plane of the substrate, at least part of the type-B color filter overlaps with the edge opening region and does not overlap with the middle opening region; and
wherein the display panel further comprises a second film layer adjacent to the light-filtering layer and located on a side of the light-filtering layer away from the substrate, and a refractive index of the second film layer is greater than a refractive index of the type-B color filter.

18. The display panel according to claim 17, wherein the type-B color filter comprises a sidewall, and a distance between the sidewall and the substrate increases along a direction from the middle opening region toward the edge opening region.

19. The display panel according to claim 1, wherein a thickness and a width of the color filter in at least part of the second opening are 0.

20. The display panel according to claim 5, wherein the second sub-pixel comprises a red second sub-pixel, and the red second sub-pixel overlaps with the second color filter along the direction perpendicular to the plane of the substrate; and/or
wherein the second sub-pixel comprises a green second sub-pixel, and the green second sub-pixel overlaps with the second color filter along the direction perpendicular to the plane of the substrate.

21. The display panel according to claim 19, wherein the second sub-pixel comprises a blue second sub-pixel, and, in the second opening overlapping with the blue second sub-pixel along the direction perpendicular to the plane of the substrate, a thickness and a width of the color filter in the second opening are 0.

22. A display device, comprising a display panel, wherein the display panel comprises:
a substrate;
a light-emitting device layer, located on a side of the substrate and comprising a first sub-pixel and a second sub-pixel; and
a light-filtering layer, located on a side of the light-emitting device layer away from the substrate and comprising a first shielding layer and a color filter, wherein the first shielding layer comprises first shielding portions, a first opening and a second opening, the first shielding portions are enclosed to form the first opening and the second opening, and along a direction perpendicular to a plane of the substrate, the first opening overlaps with the first sub-pixel, the second opening overlaps with the second sub-pixel, and the first opening comprises the color filter,
wherein, in the first opening and the second opening overlapping with the first sub-pixel and the second sub-pixel of at least one same color, along the direction perpendicular to the plane of the substrate, a thickness of the color filter in the second opening is smaller than a thickness of the color filter in the first opening, and/or along at least one same direction parallel to the plane of the substrate, a width of the color filter in the second opening is smaller than a width of the color filter in the first opening.
